(19) United States
(12) Patent Application Publication
(10) Pub. No.: US 2023/0375487 A1
(43) Pub. Date: Nov. 23, 2023

(54) DEVICE FOR CHECKING THE AUTHENTICITY OF A DATA CARRIER HAVING A ZERO-FIELD NMR FEATURE

(71) Applicant: GIESECKE+DEVRIENT CURRENCY TECHNOLOGY GMBH, Munchen (DE)

(72) Inventor: Stephan HUBER, Munchen (DE)

(21) Appl. No.: 18/030,709

(22) PCT Filed: Sep. 24, 2021
(86) PCT No.: PCT/EP2021/025367

§ 371 Date: Apr. 6, 2023

(30) Foreign Application Priority Data
Oct. 8, 2020 (DE) 10 2020 006 201.6

(51) Int. Cl. G01N 24/08; G01R 33/44; G01R 33/3415; G01R 33/36

(52) U.S. Cl. CPC G01N 24/08; G01R 33/441; G01R 33/3415; G01R 33/3635; G01R 33/3657

(57) ABSTRACT

A device is for checking the authenticity of an areal data carrier having a zero-field nuclear magnetic resonance feature, having one or more excitation coils for producing excitation pulses for the zero-field NMR feature, an array of multiple receiver coils that are independent of the excitation coils and are at least partially arranged adjacent to each other for the spatially resolved detection of the signal response of the zero-field NMR feature, the number of receiver coils in the receiver coil array being greater than the number of excitation coils, and the area covered by the excitation coils at least partially covering the area covered by the receiver coils in the receiver coil array and exceeding the size of said area.

### BACKGROUND

The present invention relates to a device for checking the authenticity of an areal data carrier having a zero-field nuclear magnetic resonance (NMR) feature.

For protection, data carriers, such as value or identification documents, but also other valuable objects, such as branded articles, are often furnished with security elements that permit the authenticity of the data carriers to be verified and that simultaneously serve as protection against unauthorized reproduction.

To facilitate an automatic authenticity check and, if applicable, an advanced sensor-based detection and processing of the data carriers furnished therewith, the security elements are often formed to be machine-readable. Security elements having machine-readable magnetic regions whose information content can be detected and evaluated by the magnetic sensor of a processing system during the authenticity check have long been used for this purpose.

Also security elements having nuclear magnetic resonance features have been used for some time for securing documents and other data carriers, as described, for example, in document EP 2 778 705 A1.

Nuclear magnetic resonance (NMR) refers to a physical effect in which the atomic nuclei of a sample in a constant magnetic field B₀ absorb and emit alternating electromagnetic fields. Here, the nuclear spins precess about the axis of the constant magnetic field with a Larmor frequency ω_{L} that is proportional to the magnetic field strength B₀. Through a suitable resonant excitation pulse of an excitation coil, the macroscopic magnetization of the sample can be tipped from the z-direction of the constant magnetic field into the xy-plane.

The deflected magnetization M_{xy} then rotates about the z-axis at the Larmor frequency and, in doing so, induces a measurable voltage in a receiver coil—which can be identical to the excitation coil. Due to inhomogeneities in the B₀ field, said macroscopically measurable voltage decreases with a certain time constant (T2*), which is referred to as free induction decay (FID). However, to a limited extent, the underlying dephasing of the magnetic moments of the individual nuclei is reversible. Specifically, if, at a time TE/2, a 180° pulse is applied, that is, an excitation pulse that is chosen in such a way that the magnetization is rotated 180°, then there is created, at the echo time TE, what is known as a spin echo, which can be measured by an electromagnetic pulse in the receiver coil.

By switching multiple 180° pulses in series, separated by TE, a train of spin echoes is created whose amplitude decreases with a time constant T2 due to spin-spin interactions. In parallel, the equilibrium magnetization along the z-axis builds back up with a characteristic time constant T1.

NMR applications have long been widespread in medical imaging and chemical structural analysis, but normally require a strong static magnetic field B₀ to induce a measurable magnetization.

For application in document security, zero-field NMR techniques, as they are known, such as nuclear quadrupole resonance (NQR) or NMR in ferromagnetic materials (NMR FM), are of particular interest. Said techniques require no external magnetic field B₀, but rather, said field is already present due to intrinsic effects in the crystal. This permits a significant simplification of the measurement setup and makes a zero-field NMR substance interesting also as a security feature in value documents such as banknotes, cards, passports or patches.

The mentioned document EP 2 778 705 A1 discloses, for banknotes, a security marking having a zero-field NMR signature, and an associated handheld sensor without an external magnetic field.

However, for a reliable authenticity check of zero-field NMR security features, multiple difficulties must be overcome. For instance, the signal-to-noise ratio (SNR) is a critical variable in every zero-field NMR measurement and should be as high as possible. The dead time τ, as it is known, refers to the time constant with which the energy stored in the resonant circuit of the sensor decreases after an excitation pulse. The dead time can be of the same magnitude as the time constant T2* such that, for a long dead time, the detection of the intense initial portion of a free induction decay is suppressed. Further, due to in- or outflow effects of a moving specimen into the sensor region, undesired artifacts can occur, especially when determining the time constants, that must be minimized for a reliable measurement. Finally, perturbations to the measured signal intensity that do not correlate with the analyzed feature quantity must be kept as minimal as possible or avoided entirely.

### SUMMARY

Proceeding from this, the object of the present invention is to specify a generic device that permits a simple and reliable authenticity check of data carriers having zero-field NMR security features.

According to the present invention, a generic device includes one or more excitation coils for producing excitation pulses for the zero-field NMR feature, and an array of multiple receiver coils that are independent of the excitation coils and are at least partially arranged adjacent to each other for the spatially resolved detection of the signal response of the zero-field NMR feature.

Here, the number N of receiver coils in the receiver coil array is greater than the number M of excitation coils, and the area F_{A} covered by the excitation coils at least partially, especially completely, covers the area F_{E} covered by the receiver coils in the receiver coil array and exceeds the size of said area F_{E}.

The area F_{A} covered by the excitation coils can especially exceed the area F_{E} covered by the receiver coils by more than 10%, by more than 20%, or even by more than 50%. In the event it is provided that the areal data carrier is transported through the device for checking the authenticity, then, in addition to the area F_{E} covered by the receiver coils, the area F_{A} covered by the excitation coils advantageously also includes the areal regions lying in front of and/or behind the covered area F_{E} in the direction of transport.

The area covered by a surface coil or surface coil array corresponds, for example, to the region in which, in operation, a significant magnetic field occurs above the coil plane, so for example a magnetic field whose field strength is more than 50% of the spatial maximum. Alternatively, the area covered by a surface coil or surface coil array can be defined by means of an envelope of the geometric dimensions of the coil/coil array, so for example as the smallest square area in which all conductor paths of the coil/coil array are included.

The receiver coils in the receiver coil array are advantageously formed by surface coils, especially in the form of conductor loops or spiral coils. Also, the excitation coils can be formed by surface coils, especially by conductor loops or spiral coils.

In one advantageous embodiment, the receiver coils in the receiver coil array each have a coil radius of 500 μm or less. As a result, the device is particularly well adapted to checking the authenticity of thin specimens having a thickness of about 100 μm. The one or more excitation coils advantageously have a significantly larger diameter, for example of about 5 mm.

Advantageously, the receiver coil array forms a one-dimensional or two-dimensional array. In particular, the receiver coil array can form a linear (one-dimensional) N×1 array, or be a rectangular n×m array where N=n*m. However, the receiver coils can also be arranged on the lattice sites of a different lattice type, for example a hexagonal lattice, or they can also comprise an irregular arrangement. In advantageous configurations, the number N of receiver coils is 2 to 10.

For better reciprocal decoupling, it can be provided that the receiver coils in the receiver coil array are arranged at least partially overlapping each other.

In one expedient embodiment, the device includes only a single excitation coil.

In one advantageous embodiment, the receiver coil array includes two or more sub-arrays whose receiver coils are each configured for a fixed receive frequency, one receiver coil each of every one of the two or more sub-arrays preferably being arranged concentrically with each other. If the receiver coil array includes multiple sub-arrays, then, advantageously, a number of sub-arrays that corresponds to the number of associated excitation coils is provided.

Advantageously, the sub-arrays have different receive frequencies, which facilitates a multispectral measurement. Advantageously, the resonance frequencies of the associated excitation coils correspond to the respective receive frequencies of the sub-arrays.

The receiver coils and/or the excitation coils are advantageously each furnished with an active decoupling device for reciprocal decoupling.

It is advantageously provided that the area F_{E} covered by the receiver coils is coordinated with the size of the zero-field NMR feature to be checked, such that the covered area F_{E} covers the entire width or even the entire area of the zero-field NMR feature.

In one preferred embodiment, it is provided that the receiver coils in the receive circuit and/or the excitation coils in the transmit circuit of the device are each furnished with a directional coupler, especially for compensating perturbations, such as amplification drift or pulse imperfections.

According to one advantageous development, the device includes an additional, single calibration coil having a reference sample that is arranged at least partially overlapping with the excitation field of the one or more excitation coils.

The device can include two or more sub-arrangements of excitation coils and receiver coils, each sub-arrangement including a single excitation coil and an associated, overlapping array composed of multiple receiver coils that are independent of the respective excitation coil. In the sub-arrangements, the area (F_{A,i}) covered by the excitation coil is greater than the area (F_{E,i}) covered by the receiver coils of the associated receiver coil array. The sub-arrangements are preferably formed to be identical to each other, that is, each includes the same configuration composed of excitation coil and receiver coils.

In one advantageous embodiment, the device defines a check area for the areal data carrier to be checked, the excitation coils and the receiver coils in the receiver coil array being arranged on the same side of the check area.

In one alternative, likewise advantageous embodiment, the device defines a check area for the areal data carrier to be checked, the excitation coils and the receiver coils in the receiver coil array being arranged slightly separated on opposite sides of the check area.

The device is advantageously configured and adapted for checking the authenticity of a nuclear quadrupole resonance (NQR) feature or an NMR feature in ferromagnetic materials.

### BRIEF DESCRIPTION OF THE DRAWINGS

Further exemplary embodiments and advantages of the present invention are explained below using the drawings, in which a depiction to scale and proportion was dispensed with in order to improve their clarity.

Shown are:

FIG. 1 a schematic diagram of a checking device according to the present invention for checking the authenticity of banknotes,

FIG. 2, including FIGS. 2(a) and 2(b), two specific configurations of the sensor frontend of a checking device according to the present invention,

FIG. 3, including FIGS. 3(a) to 3(c), some advantageous specific arrangements having M excitation coils and an array composed of N receiver coils in checking devices according to the present invention,

FIG. 4, including FIGS. 4(a) and 4(b), the use case of the verification of the completeness of a banknote that is furnished with a homogeneous, contiguous zero-field NMR feature,

FIG. 5, including FIGS. 5(a) and 5(b), a static spatially resolved measurement of a structured zero-field NMR feature, and

FIG. 6 schematically, block diagrams of the transmit circuits and receive circuits of a device according to the present invention.

### DETAILED DESCRIPTION OF VARIOUS EMBODIMENTS

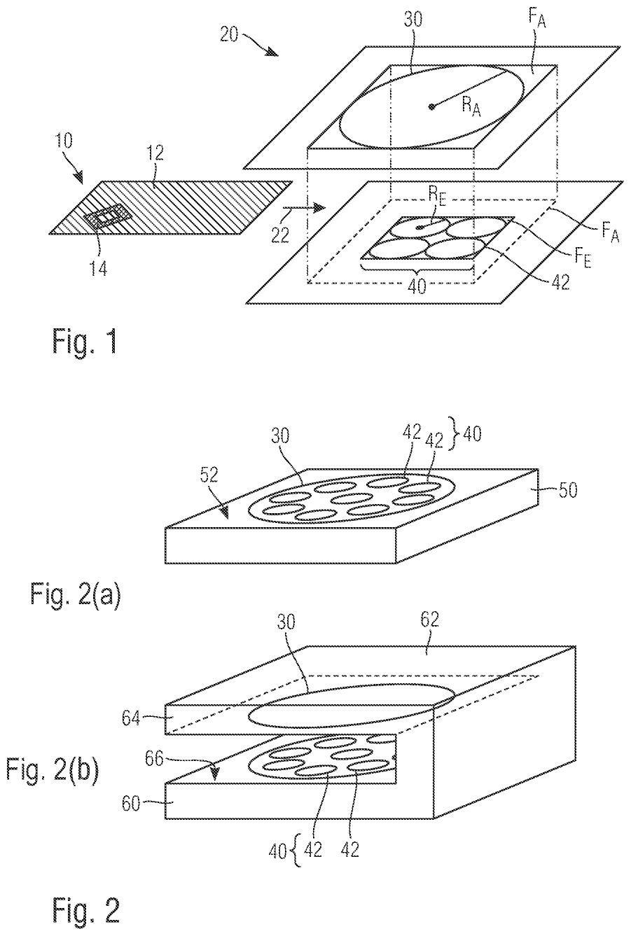

The invention will now be explained using the example of checking the authenticity of banknotes 10. With reference to FIG. 1, the banknotes 10 to be checked comprise a zero-field NMR feature that can be a feature 12 that takes up the entire area of the banknote, or that can also be present only in a certain feature region 14. The zero-field NMR feature can especially be an NQR feature or an NMR-FM feature.

For checking the authenticity, the banknote specimens 10 are guided along a transport path 22 through a checking device, of which only the sensor frontend 20 is depicted schematically in FIG. 1. The sensor frontend 20 includes, for producing excitation pulses for the zero-field NMR feature 12, 14, a single excitation coil 30 and an array 40 composed of multiple receiver coils 42 that are independent of the excitation coil 30 and with which the signal response of the feature 12, 14 can be detected spatially resolved.

In the exemplary embodiment, the receiver coils 42 are each formed by planar micro coils that have a coil radius R_{E} of 500 μm and, as a result, are optimized for the checking of thin banknote specimens. The excitation coil 30 can have, for example, a coil radius RA of 5 mm.

Also illustrated in the drawing are the area F_{A} covered by the excitation coil 30 and the area F_{E} covered by the array 40 of receiver coils 42. Here, the area F_{A} covered by the excitation coil 30 covers the area F_{E} covered by the array 40 of receiver coils 42 and significantly exceeds the size of said area F_{E} especially in the lead-in and lead-out region of the specimen 10.

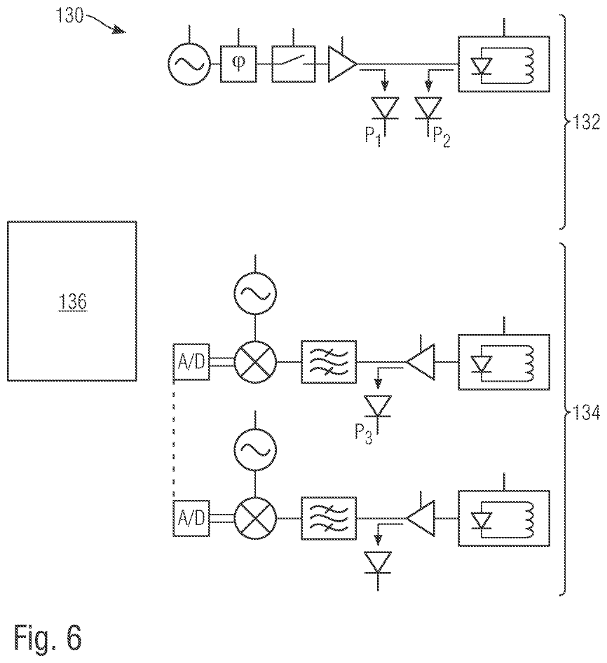

The transmit circuit of the excitation coil 30 and the receive circuits of the receiver coils 42 are each furnished with a directional coupler (FIG. 6) to compensate for perturbations, such as amplification drift or imperfections in the transmit pulse. In addition, the receiver coils 42 and, if applicable, also the excitation coil 30 are furnished with an active decoupling device for reciprocal decoupling (not shown), which can be based on, for example, PIN diodes, varactor diodes or high-frequency switches.

When checking the authenticity of areal data carriers, the checking device according to the present invention offers a range of particular advantages that will now be explained in detail.

A key parameter of pulsed NMR measurements is the signal-to-noise ratio SNR, for which the proportionality relationship

SNR˜η√Q

where η is the fill factor and Q the quality factor of the receiver coil, holds. In the device according to the present invention, the signal-to-noise ratio is especially optimized by adapting the fill factor η, which indicates the ratio of the magnetic field energy present in the sample volume to the total magnetic field energy of the receiver coil present in the space.

Here, the inventors recognized that, for thin specimens having a thickness of about 100 μm, such as banknotes or other value documents constitute, a large fill factor η and thus a high signal-to-noise ratio can be achieved by forming the receiver coils 42 as surface coils having a coil radius of R_{E}=500 μm or less.

Thus, in the checking device according to the present invention, as a result of the fill factor optimized for the areal sample geometry of the banknote specimens 10, the array 40 of small receiver coils 42 delivers, in addition to the further described advantages, a significantly better signal-to-noise ratio than a receiver composed of a larger single coil.

As a result of the split of the sensor frontend 20 into an excitation coil 30 and separate receiver coils 42, the configuration according to the present invention also permits a reduction of the dead time τ. Since the dead time of a resonant circuit—here a receive circuit—is given by

τ=2Q/ω

where Q is the quality factor and w is the resonance frequency, the dead time can be reduced by reducing the quality factor Q. However, this stands in contrast to the likewise desired high signal-to-noise ratio, which increases in proportion to √Q.

In the device described, said contrary requirements are accommodated by an active decoupling of the excitation and receiver coils that are separated from each other. For example, during the excitation pulse, with the aid of a varactor diode, the resonance frequency ω of a receiver coil 42 can be shifted in such a way that the receiver coil circuit is not excited by the excitation pulse. The dead time τ of the receiver coil 42 is thus a function of the dynamic behavior of the switch, and the quality factor Q of the receiver can be maximized independently thereof.

The inventive structure having separate coils 30 and 42 for the transmitter and receiver thus enables a reduced dead time and thus especially a higher measurement accuracy for the free induction decay than conventional structures in which the same coils serve as the transmitter and receiver.

A particularly valuable advantage of the use of an array 40 composed of receiver coils 42 consists in the achievable spatial resolution of the signal response. In zero-field NMR, the spatial resolution of an individual receiver coil 42 or a receiver coil 42, that is, here, the sensitive region of a single surface coil 42, is inversely proportional to the coil radius R_{E}. The above-mentioned small coil radius of 500 μm or less thus results in an appropriately high spatial resolution, where the spatial resolution of a measurement point is, for example, less than 1 mm.

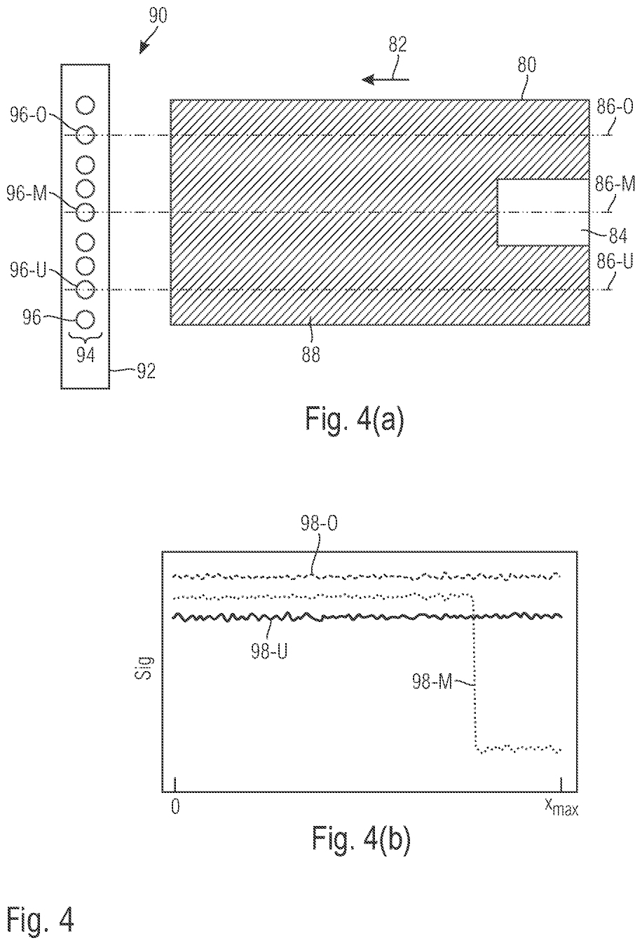

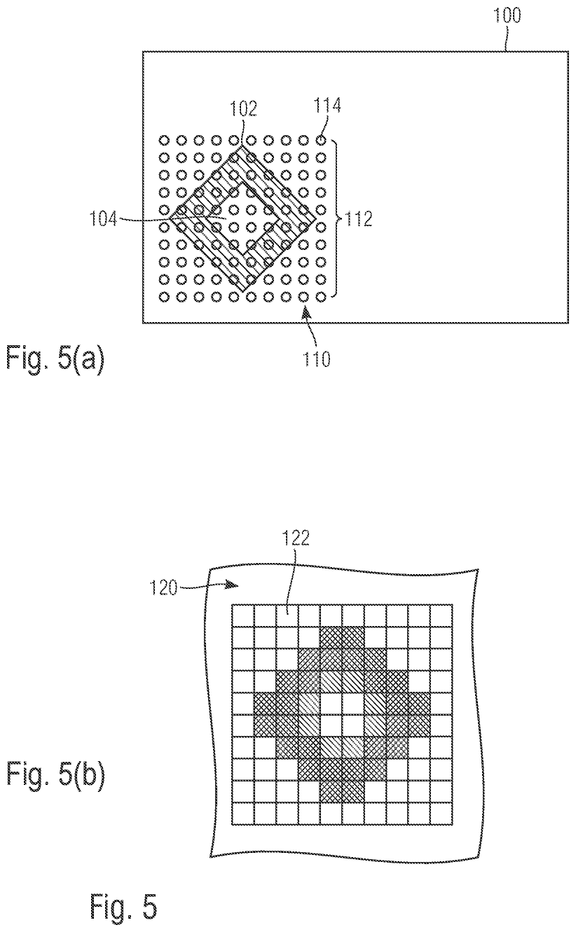

Said high spatial resolution permits, on one hand, the verification of spatially encoded security features (see FIG. 5), but on the other hand, it is also advantageous in checking NMR features that are present in large areas and homogeneously, since it enables a verification of the completeness of a specimen 10 (see FIG. 4).

To be able to measure the entire specimen 10 spatially resolved, the array 40 composed of receiver coils 42 can be configured in such a way that it covers the entire specimen. If the banknote specimen 10 is transported through the checking device 20 as in FIG. 1, it can also be sufficient to cover only the sample width with receiver coils 42, since the entire specimen is captured in the time window of a passage. However, when using an array 40 composed of receiver coils, spatial codes can also be recognized and checked in static measurements.

As explained in greater detail elsewhere, for reciprocal decoupling, the receiver coils 42 can advantageously overlap and be furnished with low-impedance receiver amplifiers. Here, every receiver coil 42 is advantageously wired with an independent receive path.

As a result of in- or outflow effects of the specimen into or out of the sensitive region of the sensor frontend 20, artifacts can occur when measuring moving specimens, especially in determining the time constants. In the proposed device, such movement artifacts are suppressed by a spatially homogeneous excitation field. As evident from FIG. 1, the area F_{A} covered by the excitation coil 30 covers not only the area F_{E} covered by the receiver coils 42 of the receiver coil array, but also those regions of the specimen 10 that, during a measurement window, move into or out of the sensitive receiver region.

In the embodiment in FIG. 1, such a homogeneous excitation field is produced by using a single, large excitation coil 30. The use of only one or a few excitation coils is possible due to the inventive separation of transmitter and receiver coils, since there is no requirement for the fill factor for the excitation coils. Thus, for moving specimens 10, the structure shown in FIG. 1 having a single large excitation coil 30 offers significant advantages compared with conventional structures having a coil array as the excitation source.

When quantifying the measurement signal, the measured signal intensity of a channel, that is, the signal intensity of an individual receiver coil 42, correlates with the feature quantity in the check feature, but also depends on the intensity and length of the excitation pulse and on the characteristics of the receiver circuit.

To compensate for spatial variations in the excitation field, the excitation field amplitude is advantageously determined at attenuated transmit power or at attenuated receiver amplification directly during operation with the aid of the array 40 of receiver coils 42. Using such a measurement, a compensation factor tailored to the receiver coil can be calculated. The configurations described enable such an approach, since, according to the present invention, the excitation coil 30 and the receiver coils 42 are separate coils.

Another possibility consists in determining the return loss of the coils and any frequency drifts directly, for example with the aid of a directional coupler, in order to, from this, either determine compensation factors, generate a control signal for possible varactor diodes for counteraction, or adapt the pulse lengths and amplitudes of the excitation pulses. To compensate for temperature drifts, temperature sensors can be provided in the amplifier paths, or the actual amplification can be determined and adjusted with the aid of detector diodes.

Further, the receiver coil array can advantageously be furnished with an additional single calibration coil together with a static reference sample. Here, such a single calibration coil should not be located in the specimen path 22, but the sensitive region of the calibration coil must overlap with a portion of the excitation field. The measured signal intensities in the calibration coil then permit a compensation for interference effects, for example of temperature drift of the excitation path, on the intensities measured at the specimen 10.

In a checking device having a sensor frontend formed in this way, for a suitable NMR feature substance, measurement times below 100 ms are already sufficient for a reliable authenticity check of a specimen. Here, potential authenticity indicators are the signal intensity, the relaxation times, the spectral distribution of the Larmor frequencies, that is, the Fourier transform of a free induction decay FID or of a spin echo, and/or the spatial arrangement and formation of the feature.

FIG. 2 illustrates two specific possible configurations of the sensor frontend, the different coils being integrated, by way of example, into a board 50. FIG. 2(a) shows a configuration having an individual excitation coil 30 and an array 40 composed of nine receiver coils 42 that are arranged within the area covered by the excitation coil 30. Here, the receiver coils 42 are integrated into the same board 50 as the excitation coil 30 but can be formed in a different copper layer of the board 50. The surface of the board 50 defines a check area 52 on which a specimen can be placed, or over which a specimen can be transported at a slight distance.

In the alternative configuration in FIG. 2(b), the sensor frontend includes, in addition to a first board 60 having the array 40 of nine receiver coils 42, a shield or holding-down device 62 that carries, in a separate board 64, the excitation coil 30. Here, too, the nine receiver coils 42 are arranged within the area of the excitation coil 30 that is projected onto the layer of the receiver coils. The surface of the first board 60 defines a check area 66 on which a specimen can be placed, or over which a specimen can be transported at a slight distance. In contrast to the configuration in FIG. 2(a), the excitation coil 30 and the receiver coils 42 in the configuration in FIG. 2(b) are not arranged on the same side, but on opposite sides of the check area.

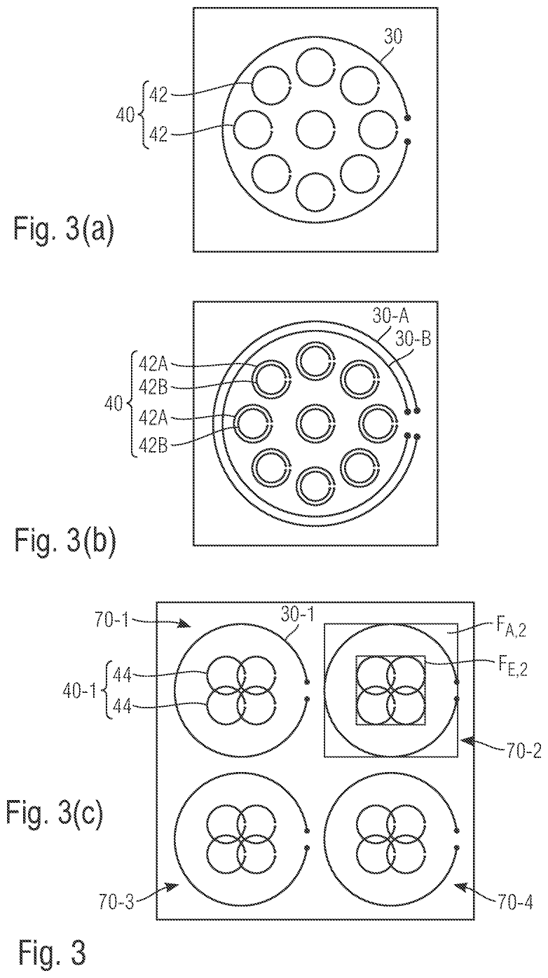

FIG. 3 shows some advantageous specific arrangements having M excitation coils and an array composed of N receiver coils in checking devices according to the present invention. The coil configuration is depicted in each case in top view, the excitation coils and the receiver coils being able to be in the same layer or in different layers and especially to be on the same side or on opposite sides of a check area for the specimens, as illustrated in FIG. 2.

First, FIG. 3(a) shows the coil configuration used in FIG. 2, in which the sensor frontend includes a single excitation coil 30 (M=1) and an array 40 composed of nine receiver coils 42 (N=9). The receiver coils 42 are arranged within the area covered by the excitation coil 30 and cover a smaller area than said excitation coil.

FIG. 3(b) shows a coil configuration in which the receiver coil array 40 includes two sub-arrays, composed in each case of nine receiver coils 42-A and 42-B, which are each tuned to a resonance frequency WA and WB, respectively, of their own. A first sub-array is formed by the nine receiver coils 42-A, a second sub-array by the nine receiver coils 42-B. In each case, one receiver coil 42-A and 42-B of the two sub-arrays are arranged concentrically with each other and electrically decoupled from each other. As a result, through appropriate wiring, multispectral measurements are possible. Accordingly, also two excitation coils 30-A, 30-B are provided in the transmit circuit of the sensor frontend such that, in this exemplary embodiment, M=2 and N=18. The receiver coils 42-A, 42-B are arranged within the area covered by the excitation coils 30-A, 30-B and cover a smaller area than said excitation coils.

A further coil configuration is illustrated in FIG. 3. In this exemplary embodiment, the sensor frontend includes a 2×2 grid of sub-arrangements 70-1, 70-2, 70-3, 70-4, each sub-arrangement 70-i including a single excitation coil 30-i and an associated array 40-i composed of receiver coils 44 that are independent of the excitation coil 30-i. Here, i=1, . . . 4, with only the excitation coil 30-1 and the array 40-1 being explicitly identified in the figure for the sake of clarity.

The receiver coils 44 of each array 40-i overlap each other for reciprocal decoupling. As depicted in the figure, in each sub-arrangement 70-i, the area F_{A,i} covered by the excitation coil 30-i is greater than the area F_{E,i} covered by the receiver coils 44 of the associated receiver coil array 40-i. Accordingly, the total area covered by the excitation coils 30-i is also greater than the total area covered by the receiver coils 44.

In the previous exemplary embodiments, the excitation and receiver coils are depicted as conductor loops by way of example, but it is understood that the coils can also be configured to be spiral shaped or rectangular. The different coils can each be arranged on the same or on different copper layers of a board or on different boards. Also, the exterior contour form of the receiver coils arrays can generally take on any arbitrary form.

FIG. 4 illustrates, as a use case, the verification of the completeness of a banknote that is furnished with a homogeneous, contiguous zero-field NMR feature 88. With reference to FIG. 4(a), a specimen 80 is moved along the transport direction 82 over a sensor frontend 90 that comprises a single excitation coil 92 and a linear array 94 of nine receiver coils 96. In the example shown, the specimen 80 constitutes a manipulated banknote in which, on the right edge of the note, a region was cut out and replaced by ordinary paper 84 without an NMR feature.

The manipulation performed is immediately evident from the measurement data of the sensor frontend 90, shown in FIG. 4(b). Shown here are the measurement curves 98-O, 98-M and 98-U for three measuring tracks 86-O, 86-M, 86-U in the upper, middle and lower portion of the specimen 80 (FIG. 4) that were captured by three appropriately arranged receiver coils 96-O, 96-M and 96-U of the sensor frontend 90.

For the sake of clarity, the measurement curves 98-O, 98-M, 98-U are depicted offset against each other vertically by a constant value and show, in each case, the relative signal strength Sig in dependence on the location x of the signal detection along the respective measuring track 86-O, 86-M, 86-U on the specimen. As a result of the signal drop in the measurement curve 98-M of the middle receiver coil 96-M, the local absence of the NMR feature in the region 84 of the specimen 80 and thus the manipulation of the banknote can immediately be concluded.

FIG. 5 illustrates a static spatially resolved measurement of a structured zero-field NMR feature. For this, FIG. 5(a) shows a card-type data carrier 100 having a feature-containing print mark 102 in the form of a rhombus having a central gap 104. The data carrier 100 is placed on the check area of a checking device according to the present invention, whose sensor frontend 110 includes a single excitation coil and a 10×10 array 112 of receiver coils 114. For the sake of clarity, in the figure, only the array 112 having the receiver coils 114 indicated by rings is depicted.

FIG. 5(b) shows the spatially resolved result 120 of the static measurement of the signal intensity in the region of the print mark 102, in each measuring field 122, the signal strength detected by the associated receiver coil 114 after excitation being depicted by the intensity of the hatching. By miniaturizing the receiver coils 114, a high spatial resolution can be achieved, such that the form of the print mark 102 including the orientation of the rhombus and the presence of the central gap 104 can easily be recognized. Thus, by modifying the print configuration, numerous possibilities for encoding the print mark 102 result.

FIG. 6 shows, schematically, block diagrams of the transmit circuits 132 and receive circuits 134 of a device 130 according to the present invention. The entire circuit can be controlled by means of a micro controller or an FPGA 136. An individual transmit circuit includes a frequency source that, in regular operation, is tuned to the Larmor frequency, a phase shifter for setting the correct pulse phases, and a pulse switch. After that comes an adjustable power amplifier for setting the pulse amplitude. Behind the amplifier are switched, for example, two directional couplers having associated detector diodes P₁ and P₂. Detector diode P₁ determines the power supplied to the respective excitation coil, and detector diode P₂, the reflected power of the excitation coil. The excitation coil itself is brought into resonance, for example with the aid of a varactor diode.

Outside of an NMR measurement, with such a circuit, a sweep of the frequency source can be performed and thus the frequency dependence of the return loss (RL) of the excitation coil determined with the aid of the detectors P₁ and P₂. Using such a measurement, the resonance frequency of the excitation coil can be determined and, with the aid of the varactor diode, said excitation coil tuned to the Larmor frequency. Furthermore, with the return loss, the quality factor Q of the excitation coil can be determined.

To produce a pulse having a defined pulse angle, that is, a pulse that deflects the nuclear spins of the sample by a defined angle, the pulse length τ can be used as a parameter. The field strength of the excitation field produced at the excitation coil, on the other hand, is a function of the quality factor Q and the power in the coil P_{coil}. The latter power can be calculated, for example, with the aid of the power determined in the detector P₁ and the RL. For a known quality factor Q and known power P_{coil}, the pulse length can be flexibly adjusted using a calibration table stored in the controller 136 or an analytical correlation, and in this way, the measurement results stabilized. Alternatively, it is also conceivable to determine the excitation field for each individual channel with the aid of receiver circuits.

Each of the receive circuits 134 shown in FIG. 6 consists of an NMR coil, the receiver coil that was brought into resonance with the aid of a varactor diode, an adjustable low-noise amplifier and a directional coupler having detector diode P₃. Finally comes a bandpass filter and an IQ demodulator having an associated local oscillator (LO) and A/D converter.

To avoid saturation of the receive circuit, with the aid of the varactor diode, the receive circuit is switched into resonance only during the measurement window. If a frequency sweep occurs in the transmit circuit, then the frequency dependence of the return loss of the receiver coil can be measured with the aid of the diodes P₁, P₂ and P₃. Here, the measurement data of the diodes P₁ and P₂, for example, are used to factor out the characteristics of the transmit circuit from the frequency dependence measured with diode P₃. In turn, the resonance frequency and the quality factor Q of the receiver coil can be determined using the measured curve. The value of the resonance frequency can then be used as an input variable for adjusting the varactor diode, and the quality factor Q can be used to correct the signal amplitudes.

1.-15. (canceled)

16. A device for checking the authenticity of an areal data carrier having a zero-field nuclear magnetic resonance (NMR) feature, having
one or more excitation coils for producing excitation pulses for the zero-field NMR feature,
an array of multiple receiver coils that are independent of the excitation coils and are at least partially arranged adjacent to each other for the spatially resolved detection of the signal response of the zero-field NMR feature,
the number of receiver coils in the receiver coil array being greater than the number of excitation coils, and
the area covered by the excitation coils at least partially covering the area covered by the receiver coils in the receiver coil array and exceeding the size of said area.

17. The device according to claim 16, wherein the receiver coils in the receiver coil array are formed by surface coils, especially in the form of conductor loops or spiral coils.

18. The device according to claim 16, wherein the receiver coils in the receiver coil array each have a coil radius of 500 μm or less.

19. The device according to claim 16, wherein the receiver coil array forms a one-dimensional or two-dimensional array.

20. The device according to claim 16, wherein the receiver coils in the receiver coil array are arranged at least partially overlapping each other.

21. The device according to claim 16, wherein the receiver coil array includes two or more sub-arrays whose receiver coils are each configured for a fixed receive frequency, one receiver coil of each of the two or more sub-arrays arranged concentrically with each other.

22. The device according to claim 21, wherein the receive frequencies of the sub-arrays are different.

23. The device according to claim 16, wherein the receiver coils and/or the excitation coils are each furnished with an active decoupling device for reciprocal decoupling.

24. The device according to claim 16, wherein the area covered by the receiver coils is coordinated with the size of the zero-field NMR feature to be checked, such that the covered area covers the entire width or even the entire area of the zero-field NMR feature.

25. The device according to claim 16, wherein the receiver coils in the receive circuit and/or the excitation coils in the transmit circuit of the device are each furnished with a directional coupler.

26. The device according to claim 16, wherein the device includes an additional, single calibration coil having a reference sample that is arranged at least partially overlapping with the excitation field of the one or more excitation coils.

27. The device according to claim 16, wherein the device includes two or more sub-arrangements of excitation coils and receiver coils, each sub-arrangement including a single excitation coil and an associated, overlapping array composed of multiple receiver coils that are independent of the respective excitation coil, and in the sub-arrangements, the area covered by the excitation coil being greater than the area covered by the receiver coils of the associated receiver coil array.

28. The device according to claim 16, wherein the device defines a check area for the areal data carrier to be checked, and the excitation coils and the receiver coils in the receiver coil array are arranged on the same side of the check area.

29. The device according to claim 16, wherein the device defines a check area for the areal data carrier to be checked, and the excitation coils and the receiver coils in the receiver coil array are arranged at a slight distance on opposite sides of the check area.

30. The device according to claim 16, wherein the device is configured and adapted for checking the authenticity of a nuclear quadrupole resonance feature or an NMR feature in ferromagnetic materials.
